(19) United States
(12) Patent Application Publication
(10) Pub. No.: US 2024/0219456 A1
(43) Pub. Date: Jul. 4, 2024

(54) MIXED SIGNAL TEST DEVICE BASED ON GRAPHICAL CONTROL

(71) Applicant: Macrotest Semiconductor Inc., Nanjing (CN)

(72) Inventors: Quanren Li, Nanjing (CN); Guoliang Mao, Nanjing (CN)

(73) Assignee: Macrotest Semiconductor Inc., Nanjing, JS (CN)

(21) Appl. No.: 17/801,528

(22) PCT Filed: Apr. 18, 2022
(86) PCT No.: PCT/CN2022/087320

§ 371 Date: Aug. 23, 2022

(30) Foreign Application Priority Data
Aug. 27, 2021 (CN) 202110992479.1

(51) Int. Cl. G01R 31/28

(52) U.S. Cl. CPC G01R 31/2884

(57) ABSTRACT

The present disclosure discloses a mixed signal test device based on graphical control, A Tester-On-board architecture is used to extend a power generation and measurement unit, an analog waveform generation and collection unit and an analog waveform control unit on a digital waveform pattern generation and measurement board. The logic control unit is configured to generate and measure a digital pattern of a System on Chip (SOC) to be tested to achieve generation and collection of the digital waveform, is configured to control the analog waveform control unit to achieve generation and collection control of an analog waveform of the SOC to be tested, and is configured to control the power generation and measurement unit to achieve generation and collection control of power of the SOC to be tested, so that generation and measurement of the digital pattern of the SOC to be tested, generation and collection control of the analog waveform, and generation and collection control of the power are simultaneously concurrently executed. The mixed signal test device based on graphical control is easy and efficient in resource coordination and control.

### TECHNICAL FIELD

The present disclosure relates to a mixed signal test device based on graphical control, and belongs to the field of Auto Test Equipment (ATE), integrated circuit ATE, semiconductor manufacturing, instruments and apparatuses, mixed signal chip tests, and the like.

### BACKGROUND ART

With the development of the Internet of Things and intelligence, more and more System On Chips (SOCs) are internally integrated with Micro Control Units (MCUs) and Analog-Digital Conversion (ADC)/Digital-Analog Conversion (DAC) analog generation and collection modules. At the same time, the price for consuming an SOC chip is also increasingly low, and chip design companies have increasingly strict requirements on the cost. Existing platforms with medium and high-speed digital-analog mixed signal testing capability are basically monopolized by foreign equipment companies, so they are expensive. A mixed signal test solution of a foreign semiconductor equipment company is basically completed by three functional boards: One board is a digital waveform pattern generation and measurement board; another board is an analog waveform generation and collection board; and the other board is a power generation and measurement board, as shown in FIG. 1.

Since resources required for a test are respectively on three independent boards, a system has a high requirement for resources; machines are bulky; and test equipment has high cost. During testing of a mixed signal chip, it is necessary to write a control function for the three boards. A writing program is complicated; static and dynamic parameters are inefficiently tested, which leads to cumbersome and inefficient coordination and control of resources required for the mixed signal testing, and makes it difficult to reduce the equipment cost.

### SUMMARY

The purpose of the invention: For the problems in original mixed signal testing, the present disclosure provides a mixed signal test device based on graphical control, which makes it easy and efficient in resource coordination and control.

Technical solution: in order to achieve the above purpose, the present disclosure adopts the technical solution below.

A mixed signal test device based on graphical control uses a Tester-On-board architecture to extend a power generation and measurement unit, an analog waveform generation and collection unit and an analog waveform control unit on a digital waveform pattern generation and measurement board; the digital waveform pattern generation and measurement board includes a board power supply unit, a digital control and collection unit, a logic control unit, a logic waveform data storage unit and an analog waveform data storage unit.

The logic control unit is connected to the power generation and measurement unit, the digital control and collection unit and the logic waveform data storage unit respectively; and the logic control unit is connected to the analog waveform control unit through a system bus. The analog waveform control unit is connected to the analog waveform generation and collection unit and the analog waveform data storage unit respectively.

The logic control unit is configured to generate and measure a digital pattern of a System on Chip (SOC) to be tested to achieve generation and collection of the digital waveform, is configured to control the analog waveform control unit to achieve generation and collection control of an analog waveform of the SOC to be tested, and is configured to control the power generation and measurement unit to achieve generation and collection control of power of the SOC to be tested, so that generation and measurement of the digital pattern of the SOC chip to be tested, generation and collection control of the analog waveform, and generation and collection control of the power are simultaneously concurrently executed.

Preferably, the mixed signal test device based on graphical control includes a system bus. The system bus is configured to receive a main control command and data of the logic control unit, and distribute the main control command and the data to the analog waveform control unit and the power generation and measurement unit.

Preferably, the mixed signal test device based on graphical control includes a board power supply unit which is configured to supply power to the logic control unit, the analog waveform control unit and the power generation and measurement unit.

Preferably, the logic control unit is connected to the digital control and collection unit through an electronic pin unit; the electronic pin unit is a 64-channel electronic pin unit which achieves logic waveform level conversion and small signal voltage and current output measurement.

Preferably the logic control unit is connected to the power generation and measurement unit through a voltage and current output measurement unit; the voltage and current output measurement unit is an 8-channel voltage and current output measurement unit; and the voltage and current output measurement unit is controlled by the logic control unit to achieve controllable voltage and current output measurement.

Preferably, there are four paths of power generation and measurement units which are controlled by the logic control unit to achieve power generation and measurement.

Preferably, there are two paths of analog waveform generation and collection units which are controlled by the logic control unit to achieve analog waveform collection.

Compared with the prior art, the present disclosure has the following beneficial effects:

1: The equipment cost is reduced. Due to the design of a shared unit, the present disclosure only needs one set of unit compared with the original technology where three independent boards are all required to be provided with a power supply, a bus controller and a vector control unit, so that the overall cost is reduced by ⅓ or above.

2: The test program development complexity is lowered. In the original test solution, when a mixed signal is tested, a power state needs to be first controlled before a test vector is executed; during the execution of the vector, an interrupt like mode needs to be invoked for multiple times to jump out of the vector execution state; in addition, dynamic parameter test, waveform generation test and the like are executed; the test development flow is complicated; and abnormalities easily occur. In the present disclosure, preset parameters are set. In the vector execution process, a power control command and a waveform generation and collection control command are synchronously sent, so that the development flow is simple.

3: The test efficiency is improved. Due to frequent interrupt processing in the test process, additional control and measurement are performed out of the vector execution, resulting in a waste of a lot of time. In the present disclosure, all preset parameters are downloaded for the first time only.

During the vector execution, power and analog waveform generation and measurement are concurrently controlled, so that the test efficiency is greatly improved.

### BRIEF DESCRIPTION OF THE DRAWINGS

FIG. 1 is a schematic diagram of an existing mixed signal test solution.

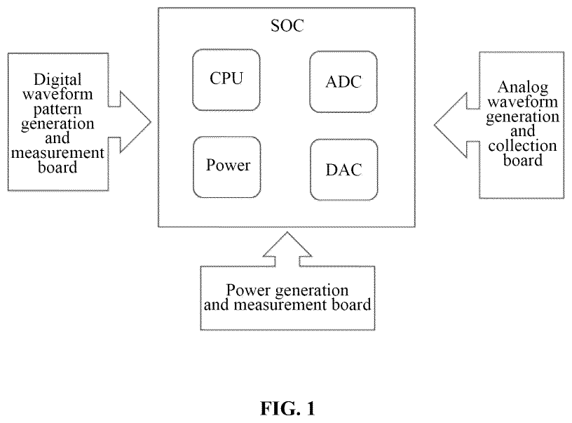

FIG. 2 is a schematic structural diagram of the present disclosure.

FIG. 3 is a schematic diagram of implementation of the present disclosure.

FIG. 4 is a flow chart of implementation of the present disclosure.

### DETAILED DESCRIPTION OF THE EMBODIMENTS

The present disclosure will be further clarified below in combination with the accompanying drawings and specific embodiments. It should be understood that these examples are only used to illustrate the present disclosure and not to limit the scope of the present disclosure. Modifications made by those skilled in the art in various forms of valence all fall within the scope defined by the appended claims of the present application.

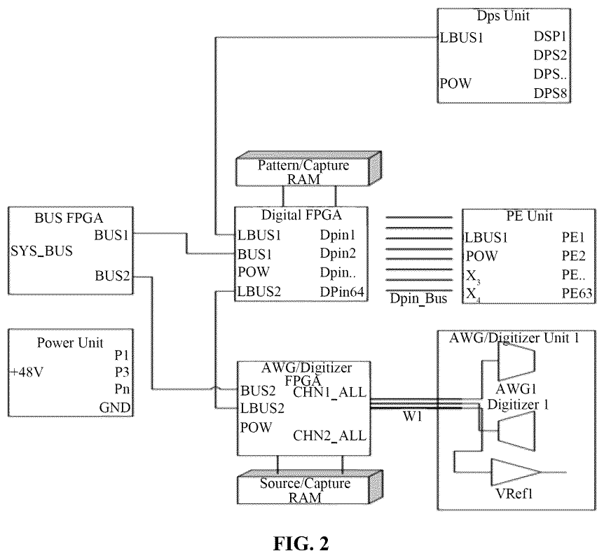

A mixed signal test device based on graphical control, as shown in FIG. 2, uses a Tester-On-board architecture to extend eight paths of power generation and measurement units, two paths of analog waveform generation and collection units and an analog waveform control unit on an original digital waveform pattern generation and measurement board; the digital waveform pattern generation and measurement board includes a system bus, a board power supply unit, a digital control and collection unit, a logic control unit, a logic waveform data storage unit and an analog waveform data storage unit.

The logic control unit is connected to the power generation and measurement unit, the digital control and collection unit and the logic waveform data storage unit respectively; and the logic control unit is connected to the analog waveform control unit through a system bus. The analog waveform control unit is connected to the analog waveform generation and collection unit and the analog waveform data storage unit respectively.

The system bus is configured to receive a main control command and data of the logic control unit, and distribute the main control command and the data to the analog waveform control unit and the power generation and measurement unit, so that a digital waveform pattern unit can directly control the power unit and the analog waveform unit to complete a high-speed test in a test vector.

The board power supply unit is configured to supply power to the power generation and measurement unit, the logic control unit and the analog waveform control unit.

The logic control unit is configured to generate and measure a digital pattern of a System on Chip (SOC) to be tested to achieve generation and collection of the digital waveform, is configured to control the analog waveform control unit to achieve generation and collection control of an analog waveform of the SOC to be tested, and is configured to control the power generation and measurement unit to achieve generation and collection control of power of the SOC to be tested, so that generation and measurement of the digital pattern of the SOC chip to be tested, generation and collection control of the analog waveform, and generation and collection control of the power are simultaneously concurrently executed.

The logic waveform data storage unit is configured to pre-store a digital pattern generation vector and store a digital waveform collection pattern.

The electronic pin unit is a 64-channel electronic pin unit which achieves logic waveform level conversion and small signal voltage and current output measurement.

The voltage and current output measurement unit is configured to 8-channel controllable voltage and current output measurement.

The analog waveform control unit is configured to perform generation and measurement control on any waveform.

The analog waveform data storage unit is configured to pre-store analog waveform data and store analog waveform collection data.

The analog waveform generation and collection subunit includes two paths of waveform generators, two paths of waveform collectors and two paths of accurate voltage reference sources, and is configured to generate and collect an analog waveform.

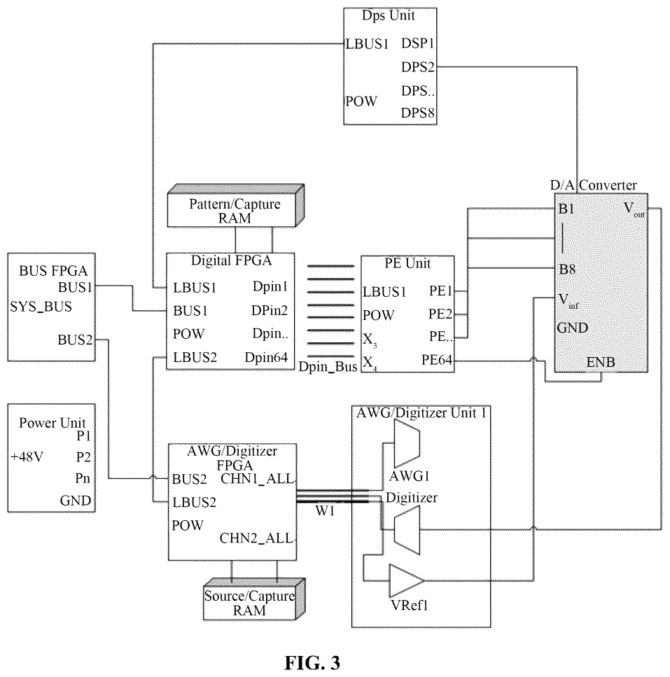

As shown in FIG. 3, DPSUnit provides power for the work of a chip under test; PE Unit provides a digital control and collection signal for the chip under test; and AWG/Digitizer Unit collects an analog signal of a device under test.

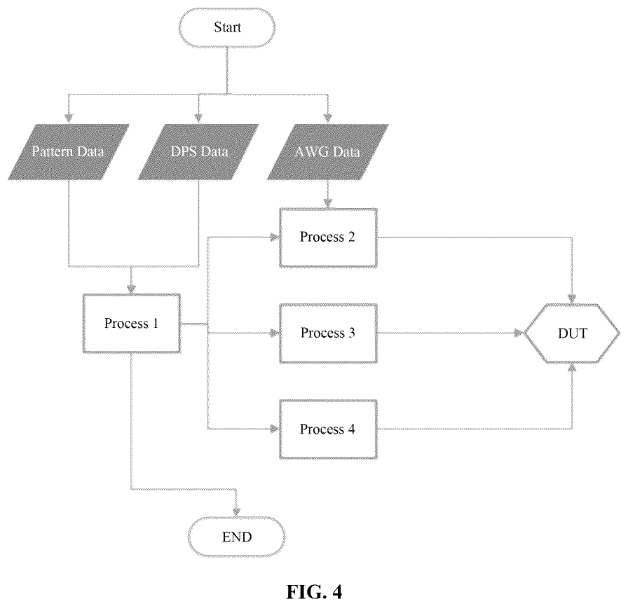

As shown in FIG. 4, before testing a mixed signal chip, the device pre-downloads multiple groups of setting data required by testing and puts the setting data into a memory (the analog waveform data storage unit Pattern Data, the power generation data storage unit DPSData, and the logic waveform data storage unit AWGData); a test main control uses a main program Process1 to run a test vector, and the test vector integrates a high-speed command set for Process2, Process3 and Process4; and the logic control unit is controlled through Process2 to perform digital pattern generation and measurement on an SOC to be tested, thus achieving generation and collection of a digital waveform. The analog waveform control unit is controlled through Process3 to control analog waveform generation and collection of the SOC to be tested. The power generation and measurement unit is controlled through Process4 to control power generation and collection of the SOC to be tested, thus achieving an effect of simultaneously and concurrently executing digital pattern generation and measurement, analog waveform generation and collection control, and power generation and collection control.

Through the Tester On board architecture, the device of the present disclosure extends eight paths of power generation and measurement subunits and two paths of analog waveform generation and collection subunits in the original digital waveform pattern generation and measurement board; and by means of a local bus in the board, the digital waveform pattern unit can directly control the power unit and the analog waveform unit to complete a high-speed test in a test vector. By the adoption of the Tester On Board architecture, the present disclosure solves the problem that the number of concurrent tests is limited by resources in the existing solution; and at the same time, by the use of a structure with a shared control unit, the problem of high cost of mixed signal test equipment is solved. With a set of high-speed commands, a function of controlling the analog waveform generation and collection unit and the power generation and measurement unit by a pattern vector is realized; and the problems of complicated writing of a mixed signal test program and low test efficiency are solved.

The structure of subunits can facilitate a user to have more choices in equipment extension, and an equipment space with the same volume can have more test resources. Since the power generation and measurement unit and the analog waveform unit share a control circuit with the digital waveform pattern unit, the equipment cost is greatly reduced. At the same time, a new set of high-speed commands are added to the digital waveform generation and measurement board to control the power generation and measurement unit and the analog waveform generation and collection unit to realize a function of graphical control of all resources, which greatly improves the test efficiency of mixed signal chips.

The above describes only the preferred embodiments of the present disclosure. It should be noted that those of ordinary skill in the art can further make several improvements and retouches without departing from the principles of the present disclosure. These improvements and retouches shall all fall within the protection scope of the present disclosure.

What is claimed is:

1. A mixed signal test device based on graphical control, wherein a Tester-On-board architecture is used to extend a power generation and measurement unit, an analog waveform generation and collection unit and an analog waveform control unit on a digital waveform pattern generation and measurement board; the digital waveform pattern generation and measurement board comprises a board power supply unit, a digital control and collection unit, a logic control unit, a logic waveform data storage unit and an analog waveform data storage unit, wherein
the board power supply unit is configured to supply power to the logic control unit, the analog waveform control unit and the power generation and measurement unit;
the logic control unit is connected to the power generation and measurement unit, the digital control and collection unit and the logic waveform data storage unit respectively; the logic control unit is connected to the analog waveform control unit through a system bus; the analog waveform control unit is connected to the analog waveform generation and collection unit and the analog waveform data storage unit respectively;
the logic control unit is configured to generate and measure a digital pattern of a System on Chip (SOC) to be tested to achieve generation and collection of the digital waveform, is configured to control the analog waveform control unit to achieve generation and collection control of an analog waveform of the SOC to be tested, and is configured to control the power generation and measurement unit to achieve generation and collection control of power of the SOC to be tested, so that generation and measurement of the digital pattern of the SOC chip to be tested, generation and collection control of the analog waveform, and generation and collection control of the power are simultaneously concurrently executed.

2. The mixed signal test device based on graphical control according to claim 1, comprising a system bus, wherein the system bus is configured to receive a main control command and data of the logic control unit, and distribute the main control command and the data to the analog waveform control unit and the power generation and measurement unit.

3. The mixed signal test device based on graphical control according to claim 2, wherein the logic control unit is connected to the digital control and collection unit through an electronic pin unit; the electronic pin unit is a 64-channel electronic pin unit which achieves logic waveform level conversion and small signal voltage and current output measurement.

4. The mixed signal test device based on graphical control according to claim 3, wherein the logic control unit is connected to the power generation and measurement unit through a voltage and current output measurement unit; the voltage and current output measurement unit is an 8-channel voltage and current output measurement unit; and the voltage and current output measurement unit is controlled by the logic control unit to achieve controllable voltage and current output measurement.

5. The mixed signal test device based on graphical control according to claim 4, wherein there are four paths of power generation and measurement units which are controlled by the logic control unit to achieve power generation and measurement.

6. The mixed signal test device based on graphical control according to claim 5, wherein there are two paths of analog waveform generation and collection units which are controlled by the logic control unit to achieve analog waveform collection.
